(19) United States
(12) Patent Application Publication
(10) Pub. No.: US 2012/0060756 A1
(43) Pub. Date: Mar. 15, 2012

(54) MASK FOR ORGANIC ELECTROLUMINESCENCE DEVICE

(75) Inventors: Takeshi OOKAWARA, Mobara (JP); Noriharu Matsudate, Kujukuri (JP); Toshiyuki Kurogi, Chiba (JP)

(73) Assignees: Canon Kabushiki Kaisha; Hitachi Displays, Ltd.

(21) Appl. No.: 13/225,689

(22) Filed: Sep. 6, 2011

(30) Foreign Application Priority Data
Sep. 10, 2010 (JP) 2010-203543

(51) Int. Cl. B05C 17/12

(52) U.S. Cl. 118/504

(57) ABSTRACT

In a mask an for organic electroluminescence device having an open hole portion of a stripe pattern, the width W of the open hole portion and the distance L from an end of the open hole portion satisfy the relational expression of ½W≦L≦20W, and the sectional shape of the open hole portion is smaller in a region extending by the distance L from the end of the open hole portion than in the other region.

### CROSS-REFERENCE TO RELATED APPLICATION

The present application claims priority from Japanese application JP2010-203543 filed on Sep. 10, 2010, the content of which is hereby incorporated by reference into this application.

### BACKGROUND OF THE INVENTION

1. Field of the Invention

The present invention relates to a mask for an organic electroluminescence device, and more particularly, to a mask for an organic electroluminescence device having an open hole portion of a stripe pattern.

2. Description of the Related Art

Various display devices such as an organic electroluminescence (OLED) display device are used as display devices of a variety of portable information equipment such as a mobile phone, a personal digital assistant (PDA), a digital camera, and a multimedia player. As the OLED display device, a low-molecular OLED and a high-molecular OLED have been developed. Particularly, since the OLED display device has excellent features such as a small thickness and a spontaneous emission of light and can be driven with a low DC voltage, the OLED display device has many superior characteristics that a liquid crystal display device does not have.

A general low-molecular OLED display device is manufactured by the use of a vacuum deposition method by patterning light-emitting layers of RGB with a high precision using a vapor deposition mask and forming a pixel array layer. In a high-molecular OLED display device, a patterning process is also carried out by a printing method. The vapor deposition mask will be described below.

In manufacturing an OLED display device, the precision of a vapor deposition mask is out of dominant factor for determining the deposition yield of the OLED and the definition thereof. Accordingly, the technique of enhancing the precision of the vapor deposition mask is an important problem in enhancing the precision of the OLED display device. With the increase in precision of the vapor deposition mask, it has been required that the pitch precision of the mask should be high. Accordingly, the pitch precision sufficient in a vapor deposition mask of the related art having a definition of 200 ppi class is not sufficient in a vapor deposition mask having a definition of 300 ppi class.

In order to cope with the increase in precision of the OLED display device, a high-definition and high-precision vapor deposition mask is necessary. On the other hand, a vapor deposition mask which is called a tension mask and produced by applying a tension to a metal foil of a mask to fix the metal foil to a frame is generally used. Accordingly, the pitch precision of the vapor deposition mask is a numerical value obtained by adding a stretched length after the application of a tension and a stretching precision to the pitch precision of the metal foil of the mask, and a more advanced technique is required for manufacturing a higher-precision vapor deposition mask.

In the related art, a stripe pattern is generally used for a high-definition OLED vapor deposition mask. A ground for using the stripe pattern is that it is a bridgeless open hole pattern and thus it is possible to design the opening ratio of the mask high. Since the mask having a stripe pattern has a continuous opening hole in the direction perpendicular to the pixel arrangement direction, it has an advantage that a vapor deposition mask is established only by satisfying the pitch precision in the arrangement direction.

On the other hand, in a slot pattern mask having a greater rigidity than the stripe pattern, the opening ratio of the mask is low due to the bridge present in the mask. In addition, since the pitch precision is also required for the direction perpendicular to the pixel arrangement direction, the technical difficulty thereof is higher than the stripe mask in enhancing the pitch precision of the mask.

Regarding a method of manufacturing a mask, an etching mask method by etching a metal foil and an electroforming mask method using an electroforming are known. The method of manufacturing a mask will be described below with reference to FIGS. 1A to 1F using an etching mask as an example. In FIG. 1A, surface treatment is performed by annealing a steel material such as a metal foil M. In FIG. 1B, a photoresist film PR is applied to both the surfaces of the metal foil M. Then, as shown in FIG. 10, patterning is carried out by exposing the metal foil M to light corresponding to opening shapes of the mask and then developing is carried out to remove the photoresist from regions to be etched. FIG. 1D shows a state where the etching E is started and FIG. 1E shows a state where the etching is ended. As shown in FIG. 1F, the etching mask is completed by removing the remaining photoresist.

The etching mask according to the related art has a problem due to a precision deterioration factor to be described below. As shown in FIG. 2B, deterioration in mask precision likely occurs due to the displacement of stripe metal ribs of the metal, which is mask. Specifically, an open hole pattern of a metal mask, which is a stripe open hole pattern, is schematically shown in FIG. 2A. The open hole pattern (having metal portions M and open hole portions H) of the metal mask has design specification of a regular open hole arrangement a.

Here, as shown in FIG. 2B, when an external force is applied to the metal mask, the metal ribs are displaced and abnormal-precision portions are formed as indicated by the dotted line A. In this case, the external force may be a vibration in the course of transporting the mask, a contact of foreign particles with the openings of the mask, and a contact of a glass substrate with the mask.

Since the variation in the open hole diameter of the mask, the displacement in the open hole position of the mask, and the like are caused in the abnormal-precision portions due to the displacement of the metal ribs of the mask, it becomes impossible to form a film with a desired deposition precision, thereby resulting in a deposition failure.

By verifying the increase in pitch precision of a mask, it can be seen that the difference between the central axis of an open hole of the mask and a vertex of an end of the open hole end causes the deterioration in precision of the mask open hole pattern. That is, FIGS. 3A to 3C show the shape of an end of an open hole portion of a stripe pattern. In FIG. 3A, an end of the open hole portion H is an open hole end of a semi-circular shape R. In case of this shape of an end, the actual end of the open hole portion has a head shape of a matchstick due to the influence of a flow of an etchant, as shown in FIG. 3B. This change in shape occurs in both a front hole and a back hole. The outline of the solid line indicates the open hole shape FH on the front side of the mask and the outline of the dotted line indicates the open hole shape BH on the back side of the mask. FIG. 3C is a diagram illustrating a cross-section of the open hole portion of the mask, where reference sign FM indicates the front side of the mask and reference sign BM indicates the back side of the mask.

In general, at the time of manufacturing an OLED vapor deposition mask, the pattern is corrected in advance in the step of designing a mask pattern to take countermeasures to this phenomenon, but the complete correction is not possible in spite of the correction. When the end of an open hole of the mask is deformed as shown in FIG. 3B, residual metal in the base of the metal portions of the mask decreases by the etching and thus the fixation strength of the ribs of the stripe mask decreases and the applied tension of the mask are not uniformly distributed in the ribs of the stripe pattern. That is, since the open hole in FIG. 3B protrudes to the right side, the metal rib on the right side is thinner (the residual metal is smaller) than the metal rib on the left side. Accordingly, when the same tension is applied to the metal ribs on the right and left sides, the mechanical strengths of the metal ribs are different from each other and thus the stretched lengths are different from each other. As a result, the mask rigidity decreases or the stretched length of the mask at the time of stretching the mask varies, thereby causing the deterioration in pitch precision or the like. In this way, the deviation in end shape of the etched pattern causes the decrease in rigidity of the stripe ribs or the decrease in positional precision.

FIGS. 4A to 4C show an example where the end shape of an open hole portion disclosed in JP-2007-234678A is employed. In this design specification, the end shape of a mask open hole H is a triangular shape T as shown in FIG. 4A. In this case, by designing the end shape of the mask open hole in a triangular shape, it is possible to reduce the amount of correction in the step of designing a mask pattern to a certain extent and it is also possible to suppress the variation of the end shape of the open hole portion into the head shape of a matchstick to a certain extent, as shown in FIG. 4B. As a result, this configuration can raise the rigidity of the mask and can contribute to the suppression of the deviation in stretched length of the mask when a tension is applied to the mask.

However, in the mask having open hole portions of a stripe pattern, the stretching at the time of applying a tension to the mask greatly depends on the end shape of the open hole portions. Accordingly, when it is intended to acquire a high-definition OLED display device, it is necessary to further suppress the deviation of end shape or the decrease in mask rigidity and to improve the pitch precision after the mask is stretched.

### SUMMARY OF THE INVENTION

An advantage of some aspects of the invention is that it provides a mask for an organic electroluminescence device which can achieve the improvement in mask rigidity and which can raise the pitch precision after the mask is stretched.

The following configurations can be employed to achieve the above-mentioned advantage.

(1) A mask for an organic electroluminescence device having an open hole portion of a stripe pattern, wherein the width W of the open hole portion and the distance L from an end of the open hole portion satisfy the relational expression of ½W≦L≦20W, and the sectional shape of the open hole portion is smaller in a region extending by the distance L from the end of the open hole portion than in the other region.

(2) The mask for an organic electroluminescence device according to (1), wherein the open hole portion is formed by etching a metal foil forming the mask from both the surfaces, and the taper angle in the sectional shape of the open hole portion satisfies the relational expression of θₒ<θ<90°, where θ represents the taper angle in the region extending by the distance L from the end of the open hole portion and θₒ represents the taper angle in the other region.

(3) The mask for an organic electroluminescence device according to (2), wherein the taper angle varies stepwise or continuously between the region extending by the distance L from the end of the open hole portion and the other region or in the region extending by the distance L from the end of the open hole portion.

(4) The mask for an organic electroluminescence device according to any one of (1) to (3), wherein the end shape of the open hole portion is a triangular shape on a semi-circular shape.

In the mask for an organic electroluminescence device having an open hole portion of a stripe pattern according to the invention, since the width W of the open hole portion and the distance L from an end of the open hole portion satisfy the expression of “½W≦L≦20W”, and the sectional shape of the open hole portion is smaller in a region extending by the distance L from the end of the open hole portion than in the other region. Accordingly, it is possible to raise the mask rigidity at the end of the open hole portion and in the vicinity of the end. As a result, it is possible to control the stretching precision of the mask with a high precision and to enhance the pitch precision.

By raising the mask rigidity at the end of the open hole portion and in the vicinity of the end, it is possible to uniformize the mask tension and thus to raise the entire rigidity of the mask. It is possible to improve the manufacturing yield of the mask due to the increase in the pitch precision of the mask and the mask rigidity. By employing this mask, it is possible to achieve an increase in definition of an OLED display device.

### BRIEF DESCRIPTION OF THE DRAWINGS

FIGS. 1A to 1F are diagrams schematically illustrating a process of manufacturing an etching mask according to the related art.

FIG. 2A is a diagram illustrating a mask having of a stripe pattern according to the related art which has normal open hole portions.

FIG. 2B is a diagram illustrating a mask of a stripe pattern according to the related art which has open hole portions whose metal ribs are deformed.

FIG. 3A is a diagram illustrating a design specification according to the related art in which an end of an open hole portion has a semi-circular shape.

FIG. 3B is a diagram illustrating the final shape of the design specification shown in FIG. 3A after being etched.

FIG. 3C is a sectional view of the mask shown in FIG. 3B.

FIG. 4A is a diagram illustrating a design specification according to the related art in which the end of an open hole portion has a triangular shape.

FIG. 4B is a diagram illustrating the final shape of the design specification shown in FIG. 4A after being etched.

FIG. 4C is a sectional view of the mask shown in FIG. 4B.

FIG. 5A is a diagram illustrating an example of a design specification of an open hole portion in a mask for organic electroluminescence device according to an embodiment of the invention.

FIG. 5B is a diagram illustrating the final shape of the design specification shown in FIG. 5A after being etched.

FIGS. 6A to 6C are sectional views taken along lines VIA-VIA, VIB-VIB, and VIC-VIC of FIG. 5B, respectively.

FIG. 7 is a diagram illustrating an example of a photoresist pattern formed on a back surface of a mask.

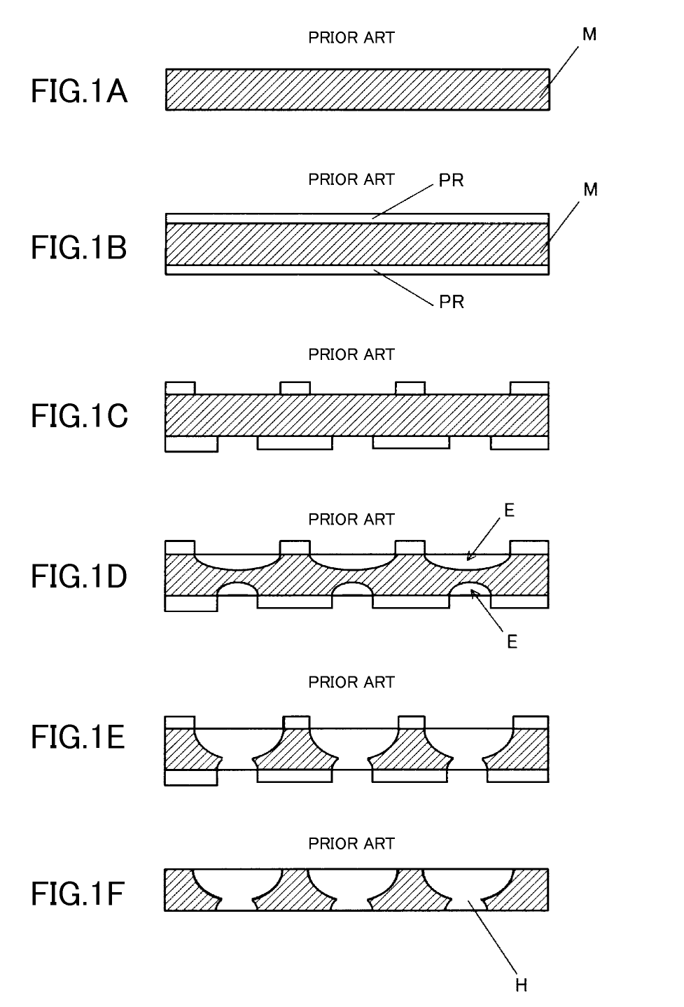

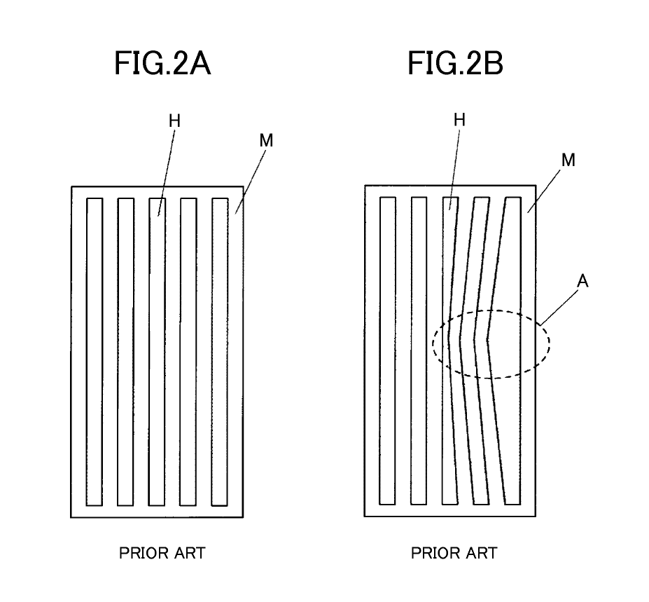

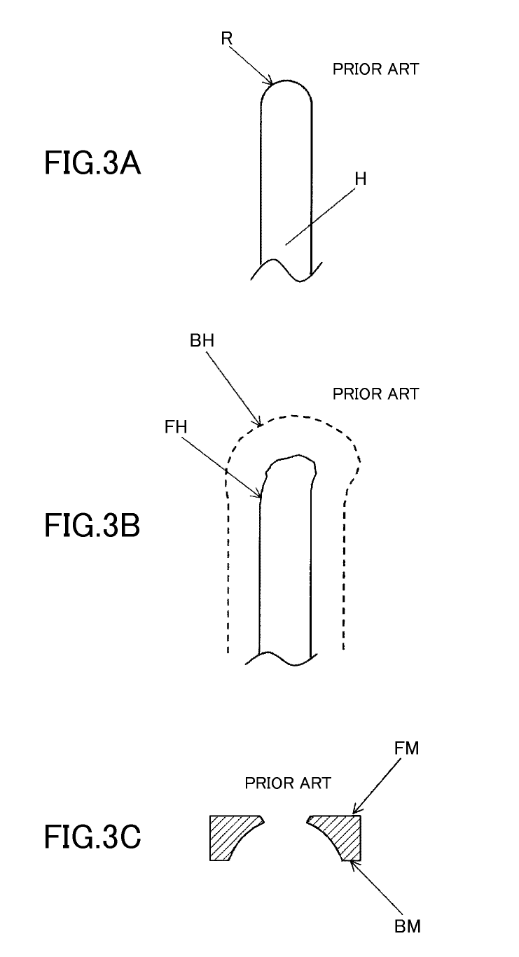

### DETAILED DESCRIPTION OF THE INVENTION

Hereinafter, a mask for an organic electroluminescence device according to an embodiment of the invention will be described in detail with reference to the accompanying drawings.

According to this embodiment, there is provided a mask for an organic electroluminescence device having an open hole portion of a stripe pattern, wherein the width W of the open hole portion and the distance L from an end of the open hole portion satisfy the relational expression of ½W≦L≦20W, and the sectional shape of the open hole portion is set smaller in a region extending by the distance L from the end of the open hole portion than in the other region.

That is, the sectional area of the open hole portion is set smaller at the end of the open hole portion and in the vicinity of the end in the mask according to this embodiment. Accordingly, the volume of the residual metal increases and it is thus possible to raise the mechanical strength of the ends of the open hole portions or the rib portions. As a result, it is possible to uniformly distribute a mask tension to the stripe rib portions at the time of stretching the mask to a predetermined size by applying the tension to the mask and also to enhance the pitch precision of a metal foil of the mask due to the improvement in the rigidity of the stripe rib portions and the improvement in resistance to a transport tension at the time of manufacturing the metal foil of the mask, thereby achieving both the increase in rigidity of the mask and the improvement in pitch precision of the mask.

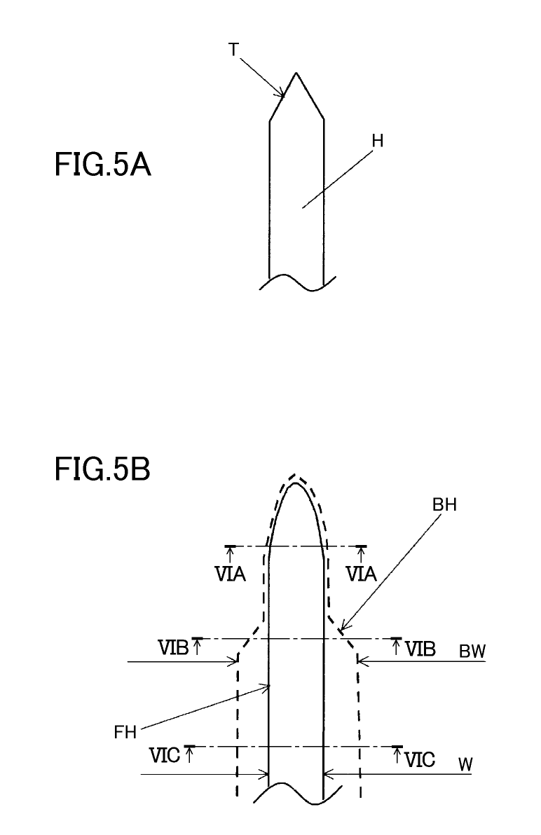

A specific shape of an end of an open hole portion will be described below with reference to FIGS. 5A to 7, where an etching mask is used. FIG. 5A shows an example of a design specification of an open hole portion H and the end shape thereof employs the triangular shape T disclosed in JP-2007-234678A. In this embodiment, the end shape is not limited to the triangular shape, but may be a semi-circular shape, in order to achieve the increase in the pitch precision or the increase in the mask rigidity.

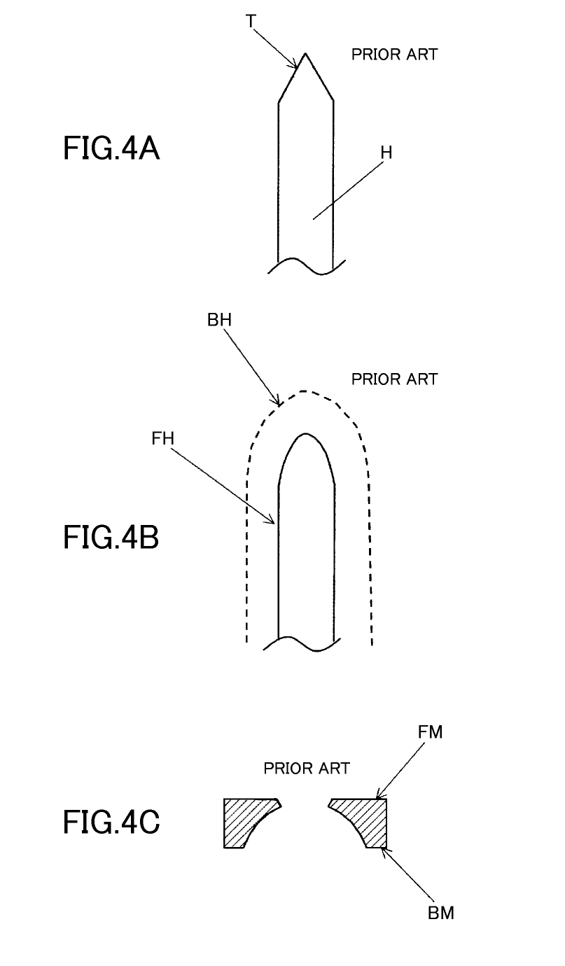

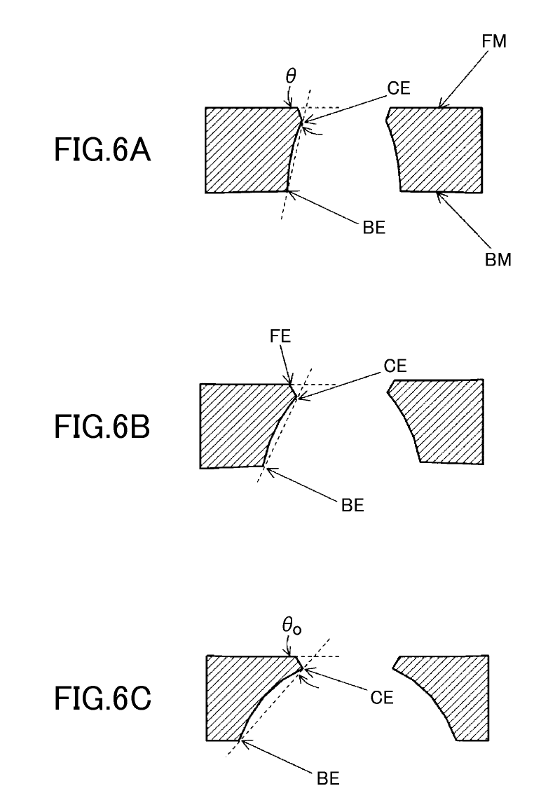

As shown in FIG. 5B, in the mask for an organic electroluminescence device according to this embodiment, the shape of an open hole portion FH on the front side of the mask and the shape of an open hole portion BH on the back side of the mask are different from those of the related art shown in FIG. 4B. Clearly seen from the sectional shapes of the open hole portion H, as shown in FIGS. 6A to 6C, the width BW of the open hole portion on the back side of the mask is smaller in the sectional position (FIG. 6A) at an end or in the vicinity of the end than in the sectional position (FIG. 6C) of the other open hole portion. This means that the sectional area of the open hole portion is smaller at the end or in the vicinity of the end than at the other portion, whereby the volume of the residual metal of the metal ribs increases.

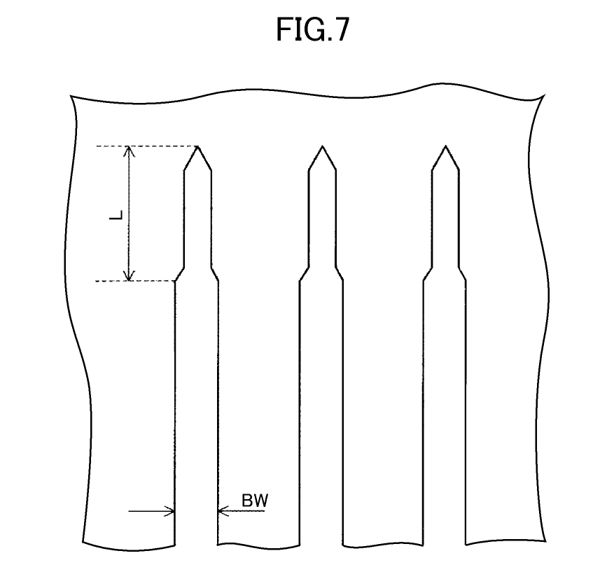

When it is intended to form the open hole portion BH on the back side of the mask as shown in FIG. 5B, the width of the open hole portion in a photoresist pattern is set smaller than the normal width BW, in the vicinity of an end of the open hole portion in the stripe pattern, that is, within the range extending by the distance L from the end, as shown in FIG. 7. When the distance L is less than half the open hole width of the mask, a part at the end of the open hole portion and in the vicinity of the end, in which the strength of the rib is improved, is small and it is not possible to satisfactorily expect the increase in mask rigidity or the improvement in pitch precision as in this embodiment. In FIG. 5B, the open hole width W of the mask seems to be equal to the width of the open hole FH on the front side of the mask, but actually, the open hole width W (the width of a part in which the front hole is connected to the back hole or the narrowest part of the open hole portion of the mask) of the mask is slightly smaller than the width of the open hole FH on the front side of the mask, as shown in FIGS. 6A to 6C.

On the other hand, when the distance L is greater than 20 times the open hole width W of the mask, the shape of the open hole portion (after the etching) formed by both the open hole on the front side of the mask and the open hole on the back side of the mask in the region extending by the distance L from the end may be different from the shape in the other region. This part (the range of the distance L) having a different open hole shape cannot be used as an image display area. Accordingly, when the distance L increases, a useless frame part not contributing to the display increases. Therefore, it is preferable that the distance L is set to be equal to or less than 20 times the open hole width W of the mask.

As shown in FIGS. 6A to 6C, when the open hole portion of the mask is formed by etching a metal foil from both the sides, the taper angle in the sectional shape of the open hole portion is different from those taken along line VIA-VIA of FIG. 5B, taken along line VIB-VIB, and line VIC-VIC. As can be clearly seen from the comparison of FIGS. 6A and 6C, the relationship between the taper angle θ (FIG. 6A) in the region extending by the distance L from the end of the open hole portion and the taper angle θₒ (FIG. 6C) in the other region satisfies the following relational expression.

θₒ<θ<90°

As shown in FIG. 6A, the taper angle θ in this embodiment is expressed by an angle formed by a straight line connecting an open edge BE on the back side of the mask and the narrowest part (CE) of the through open hole portion and the front surface of the mask, but is not limited to this definition. For example, an angle formed by a straight line connecting the open edge BE on the back side of the mask and the open edge FE (FIG. 6B) on the front side of the mask and the front surface of the mask may be used. In the sectional shape of the open hole portion shown in FIGS. 6A and 6C, the outline of the inclined surface inside the rib is expressed by a main angle of the inclined surface and the taper angle in this embodiment corresponds to the angle.

In FIGS. 6A to 6C, the taper angle stepwise varies between the region (FIG. 6A) extending by the distance L from the end of the open hole portion and the other region (FIG. 6C), but this embodiment is not limited to this configuration. The taper angle may continuously vary in the region extending by the distance L from the end of the open hole portion. In this case, the pattern on the back side of the mask shown in FIG. 7 can be configured so that the width continuously varies in the range extending by the distance L.

In this embodiment, it is possible to improve the rigidity of the base of the stripe rib by properly designing the taper angle of the end of the open hole portion. Accordingly, at the time of stretching the metal foil of the mask, it is possible to efficiently apply a tension to the stripe ribs of the mask. Since the deviation in stretched length in the mask pattern decreases, it is possible to improve the pitch precision of the mask. In addition, since the displacement due to an external stress such as a transport tension in the mask manufacturing process decreases, it is possible to expect the improvement in pitch precision of the metal foil of the mask.

The following advantages can be expected in a display device using the mask for an organic electroluminescence device according to this embodiment:

(1) increase in definition of an OLED display device;

(2) decrease in cost of the mask due to the improvement in yield of the mask;

(3) improvement in OLED deposition (printing) yield due to the improvement in pitch precision of the mask;

(4) improvement in productivity of OLED due to the improvement in rigidity of the mask; and

(5) decrease in cost of the OLED display device.

Although the etching mask has been mainly described, the same advantages can be expected in an electroforming mask by setting the sectional area smaller at an end of an open hole portion or in the vicinity of the end smaller than the other region.

A mask according to the related art having the shape shown in FIG. 4B and a mask according to this embodiment having the shape shown in FIG. 5B were manufactured and the characteristics thereof were compared. Here, 36% Ni—Fe was employed as the mask material, the thickness of the masks was set to 40 μm, the open hole diameter (width) of the masks was designed to 31 μm, and the pitch of the masks was designed to 93 μm.

The comparison revealed that the precisions of the open hole portions of the masks were both 31±3 μm, however, when a tension was applied thereto, the pitch precision (deviation) of the mask according to the related art was ±5 μm but the pitch precision according to this embodiment was ±4 μm. When the rigidities of the masks were measured with a static load, the rigidity of the mask according to this embodiment was in the range of 105 to 110 with respect to the mask rigidity of 100 according to the related art. It could be confirmed that the pitch precision and the mask rigidity are improved.

As described above, the embodiment of the invention can provide a mask for an organic electroluminescence device having an open hole portion of a stripe pattern, in which rigidity can be improved and the pitch precision after stretched can be enhanced.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A mask for an organic electroluminescence device having an open hole portion of a stripe pattern,
wherein the width W of the open hole portion and the distance L from an end of the open hole portion satisfy the relational expression of ½W≦L≦20W, and
wherein the sectional shape of the open hole portion is smaller in a region extending by the distance L from the end of the open hole portion than in the other region.

2. The mask for an organic electroluminescence device according to claim 1, wherein the open hole portion is formed by etching a metal foil forming the mask from both the surfaces, and
wherein the taper angle in the sectional shape of the open hole portion satisfies the relational expression of θₒ<θ<90°, where θ represents the taper angle in the region extending by the distance L from the end of the open hole portion and θₒ represents the taper angle in the other region.

3. The mask for an organic electroluminescence device according to claim 2, wherein the taper angle varies stepwise or continuously between the region extending by the distance L from the end of the open hole portion and the other region or in the region extending by the distance L from the end of the open hole portion.

4. The mask for an organic electroluminescence device according to claim 1, wherein the end shape of the open hole portion is a triangular shape or a semi-circular shape.
